(19) United States
(12) Patent Application Publication
(10) Pub. No.: US 2025/0072244 A1
(43) Pub. Date: Feb. 27, 2025

(54) DISPLAY PANEL AND DISPLAY DEVICE

(71) Applicant: HEFEI VISIONOX TECHNOLOGY CO., LTD., Hefei (CN)

(72) Inventors: Bo RAO, Hefei (CN); Xiaoxi SUN, Hefei (CN); Yuan YAO, Hefei (CN); Xuejing ZHU, Hefei (CN)

(73) Assignee: HEFEI VISIONOX TECHNOLOGY CO., LTD., Hefei (CN)

(21) Appl. No.: 18/944,510

(22) Filed: Nov. 12, 2024

(30) Foreign Application Priority Data
Jun. 28, 2024 (CN) 202410873064.6

(51) Int. Cl. H10K 59/131; G06F 3/041; G06F 3/044; H10K 59/122; H10K 59/40

(52) U.S. Cl. CPC H10K 59/131; G06F 3/0412; G06F 3/044; H10K 59/122; H10K 59/40

(57) ABSTRACT

A display panel includes a display area and a first wiring area. The display panel includes a substrate, a partition structure, a first touch-control member, a wiring layer, and a first conducting member. The partition structure surrounds and defines a first opening. The first touch-control member is located in the first opening. The first touch-control member is electrically insulated from the partition structure. The wiring layer includes a first conducting line and a second conducting line. The first conducting line is electrically connected to the partition structure. The first conducting line is located in the first wiring area. The second conducting line is electrically connected to the first touch-control member. The second conducting line is located in the display area. The first conducting member is located in the first wiring area. The first conducting member and the second conducting line are electrically connected and are located in different layers.

### CROSS-REFERENCE TO RELATED APPLICATIONS

This application claims priority to Chinese Patent Application No. 202410873064.6, entitled “DISPLAY PANEL AND DISPLAY DEVICE” filed on Jun. 28, 2024, the content of which is hereby incorporated herein in its entirety by reference.

### TECHNICAL FIELD

The present application relates to the field of display technology, in particular to a display panel and a display device.

### BACKGROUND

Organic light-emitting diodes (OLEDs) have received widespread attentions and become a new generation displaying solution due to their characteristics of self-luminescence, high brightness, wide viewing angle, high contrast ratio, flexibility, low energy consumption, etc. OLED displays have gradually replaced traditional liquid crystal displays and are widely used in mobile phone screens, computer monitors, full-color televisions, etc.

There is an increasing demand for incorporating touch panels into OLED display devices, so that information can be sent to the OLED display devices by touching the surface of the touch panels with the hand or a separate input member. The touch panels are generally classified into three types: an add-on type, an on-cell type, and an in-cell type. An add-on type touch panel is mounted on an outer surface of an OLED display device. An on-cell type touch panel is disposed on an OLED display panel. An in-cell type touch panel is installed in an OLED display panel. The in-cell type touch panels have advantages such as a low production cost and a thin thickness, rendering them to be gradually promoted and applied. However, the existing OLED display panels prepared with the in-cell technology still have issues such as display defects.

### SUMMARY

In view of the above, the present application provides a display panel and a display device.

An aspect of the present application is to provide a display panel. The display panel includes a display area and a first wiring area. The first wiring area is located at a side of the display area. The display panel includes a substrate, a partition structure, a first touch-control member, a wiring layer, and a first conducting member. The partition structure is disposed at a side of the substrate. At least a portion of the partition structure surrounds and defines a first opening. At least a portion of the first touch-control member is located in the first opening. The first touch-control member is electrically insulated from the partition structure. The wiring layer includes a first conducting line and a second conducting line. The first conducting line is electrically connected to the partition structure. At least a portion of the first conducting line is located in the first wiring area. The second conducting line is electrically connected to the first touch-control member. At least a portion of the second conducting line is located in the display area. At least a portion of the first conducting member is located in the first wiring area. The first conducting member and the second conducting line are electrically connected to each other and are respectively located in different layers

According to the display panel provided in the embodiment of the present application, the first conducting line is electrically connected to the partition structure, and at least a portion of the first conducting line is located in the first wiring area. The second conducting line is electrically connected to the first touch-control member, and at least a portion of the second conducting line is located in the display area. At least a portion of the first conducting member is located in the first wiring area. The first conducting member and the second conducting line are electrically connected to each other and are located in different layers. As such, the second conducting line in the first wiring area can be replaced with the first conducting member to transmit a touch signal from the second conducting line. Accordingly, on the one hand, it can effectively reduce the probability of interference between the first conducting line and the second conducting line in the first wiring area, thereby improving the display effect of the display panel. On the other hand, it can effectively mitigate occupation of the wiring space for the first conducting line in the first wiring area by the second conducting line, which ensures the layout space for the first conducting line in the first wiring area, thereby further improving the display effect of the display panel.

In some embodiments, the partition structure includes a plurality of partition sub-structures. Adjacent partition sub-structures are spaced from each other to define the first opening.

Optionally, each partition sub-structure defines at least one second opening.

Optionally, an orthographic projection of the partition sub-structure on the substrate has a grid shape.

Optionally, the orthographic projection of the partition sub-structure on the substrate has a shape of a closed ring.

Optionally, the partition structure includes a conductive connection portion. Adjacent partition sub-structures are electrically connected to each other through the conductive connection portion. The conductive connection portion is electrically insulated from the first touch-control member.

Optionally, the first conducting member and the partition structure are disposed in a same layer and are electrically insulated from each other.

Optionally, an orthographic projection of the first conducting member on the substrate overlaps with an orthographic projection of the first conducting line on the substrate, forming an overlapping area located in the first wiring area.

Optionally, the wiring layer is located in the substrate.

In some embodiments, the first touch-control member includes a plurality of touch-control sub-electrodes. The plurality of touch-control sub-electrodes are spaced from each other and are disposed on a same side of the substrate.

Optionally, each touch-control sub-electrode at least partially surrounds a periphery of at least one partition sub-structure.

Optionally, the plurality of touch-control sub-electrodes are disposed in rows along a first direction and in columns along a second direction, and the second direction intersects with the first direction.

In some embodiments, the touch-control sub-electrode includes a plurality of sub-electrode units. The plurality of sub-electrode units are spaced from each other. The sub-electrode units are electrically connected to the second conducting line.

Optionally, the conductive connection portion is located between two adjacent sub-electrode units.

Optionally, each sub-electrode unit includes a first extension portion extending along the first direction. The first extension portion is located between two adjacent partition sub-structures along the second direction. The first extension portion is electrically connected to the second conducting line.

Optionally, each sub-electrode unit further includes a second extension portion connected to the first extension portion. The second extension portion extends along the second direction. The second extension portion is located between two adjacent partition sub-structures along the first direction.

Optionally, the second conducting line extends along the second direction.

In some embodiments, the display panel further includes a second touch-control member, and in the first touch-control member and the second touch-control member, one is configured to be an emitter electrode, and the other is configured to be a receiver electrode.

Optionally, the second touch-control member is located in the first opening. The second touch-control member is electrically insulated from the partition structure and the first touch-control member.

Optionally, the second touch-control member is located at a side of the first touch-control member away from the substrate.

Optionally, the display panel further includes a first functional layer. The first functional layer is disposed at a side of the partition structure away from the substrate. The second touch-control member is disposed at a side of the first functional layer away from the substrate.

Optionally, the first touch-control member includes a plurality of first sub-electrodes. The plurality of first sub-electrodes extend along the second direction and are spaced apart from each other along the first direction. The second touch-control member includes a plurality of second sub-electrodes. The plurality of second sub-electrodes extend along the first direction and are spaced apart from each other along the second direction. The first direction intersects with the second direction.

Optionally, the wiring layer further includes a third conducting line. The third conducting line is electrically connected to the second touch-control member.

In some embodiments, the display panel further includes a first through-hole connection structure and a second through-hole connection structure. The partition structure is electrically connected to the first conducting line via the first through-hole connection structure. The first touch-control member is electrically connected to the second conducting line via the second through-hole connection structure.

Optionally, the display panel further includes a first wire-changing area. The first wire-changing area is located between the display area and the first wiring area. The display panel further includes a third through-hole connection structure, and the third through-hole connection structure is located in the first wire-changing area. The second conducting line is electrically connected to the first conducting member via the third through-hole connection structure.

Optionally, the display panel further includes a dam structure and an encapsulation structure. The dam structure is disposed at a side of the substrate. At least a portion of the dam structure is disposed at a side of the first wiring area away from the display area. The encapsulation structure covers the partition structure and the first touch-control member. The encapsulation structure includes an organic encapsulation layer. A boundary of the organic encapsulation layer is located at a side of the dam structure adjacent to the display area.

Optionally, the dam structure surrounds the display area.

Optionally, the encapsulation structure further includes a first inorganic encapsulation layer and a second inorganic encapsulation layer. The first inorganic encapsulation layer is located at a side of the organic encapsulation layer adjacent to the substrate. The second inorganic encapsulation layer is located at a side of the organic encapsulation layer away from the substrate. The first inorganic encapsulation layer and the second inorganic encapsulation layer cover the dam structure.

In some embodiments, the wiring layer further includes a fourth conducting line. An orthographic projection of the fourth conducting line on the substrate overlaps with an orthographic projection of the dam structure on the substrate. The first conducting member extends to the side of the dam structure adjacent to the display area and is electrically connected to the fourth conducting line.

Optionally, the display panel further includes a second conducting member. The second conducting member is located at a side of the dam structure away from the display area. The second conducting member and the fourth conducting line are electrically connected to each other and are located in different layers.

Optionally, the second conducting member and the first conducting member are disposed in a same layer.

Optionally, the dam structure includes a first sub-layer and a second sub-layer. The first sub-layer is located at a side of the fourth conducting line adjacent to the substrate. The second sub-layer is located at a side of the fourth conducting line away from the substrate.

Optionally, an orthographic projection of the fourth conducting line on the substrate covers the orthographic projection of the dam structure on the substrate.

In some embodiments, the display panel further includes a bending area. The bending area is located at a side of the dam structure away from the display area. The wiring layer further includes a fifth conducting line. At least a portion of the fifth conducting line is located in the bending area. The first conducting member extends to a side of the bending area adjacent to the display area and is electrically connected to the fifth conducting line.

Optionally, the display panel further includes a third conducting member. The third conducting member is located at a side of the bending area away from the display area. The third conducting member and the fifth conducting line are electrically connected to each other and are located in different layers.

Optionally, the third conducting member and the first conducting member are disposed in a same layer.

In some embodiments, the display panel further includes a bonding area. The bonding area is located at a side of the dam structure away from the display area. The display panel further includes a chip disposed in the bonding area. The chip is electrically connected to the first conducting line and the first conducting member.

Optionally, the wiring layer further includes a sixth conducting line. At least a portion of the sixth conducting line is located in the bonding area. The sixth conducting line is electrically connected to the chip and the first conducting member.

Optionally, the display panel further includes a second wire-changing area. The second wire-changing area is located at a side of the bonding area adjacent to the display area.

The display panel further includes a fourth through-hole connection structure, and the fourth through-hole connection structure is located in the second wire-changing area. The sixth conducting line extends to the second wire-changing area. The sixth conducting line is electrically connected to the first conducting member through the fourth through-hole connection structure.

In some embodiments, the partition structure further includes a first partition portion and a second partition portion. The second partition portion is disposed at a side of the first partition portion away from the substrate. An orthographic projection of the first partition portion on the substrate falls within an orthographic projection of the second partition portion on the substrate. The second conducting line is electrically connected to the first partition portion.

Optionally, a material of the second partition portion includes an electrically insulating material.

Optionally, a material of the second partition portion includes an electrically conductive material.

In some embodiments, the first touch-control member includes a third partition portion. The third partition portion and the first partition portion are disposed in a same layer and are electrically insulated from each other.

Optionally, the first touch-control member further includes a fourth partition portion. The fourth partition portion is disposed at a side of the third partition portion away from the substrate. The fourth partition portion and the second partition portion are disposed in a same layer and are electrically insulated from each other.

Optionally, an orthographic projection of the third partition portion on the substrate falls within an orthographic projection of the fourth partition portion on the substrate.

In some embodiments, the display panel further includes a light-emitting functional portion. The light-emitting functional portion is disposed in the second opening. The light-emitting functional portion is spaced from the partition sub-structure.

Optionally, the display panel further includes a first electrode. The first electrode is located at a side of the light-emitting functional portion adjacent to the substrate. The first electrode is electrically insulated from the partition structure.

Optionally, the display panel further includes a second electrode. The second electrode is located at a side of the light-emitting functional portion away from the substrate. The second electrode is electrically connected to the partition sub-structure.

In some embodiments, the display panel further includes a first insulating layer. The first insulating layer is disposed between the partition structure and the first electrode. The first insulating layer defines a third opening 181a. The third opening is located corresponding to the second opening. At least a portion of the light-emitting functional portion is disposed in the third opening. The third opening exposes the first electrode.

Optionally, the orthographic projection of the partition sub-structure on the substrate is located at a periphery of an orthographic projection of the third opening on the substrate.

In some embodiments, the first electrode and the wiring layer are disposed in a same layer and are electrically insulated from each other.

In some embodiments, the wiring layer is located at a side of the first electrode adjacent to the substrate. The wiring layer is electrically insulated from the first electrode.

Optionally, the display panel further includes a second insulating layer. The second insulating layer is disposed between the wiring layer and the first electrode.

According to another aspect of the present application, a display panel is provided. The display panel includes a display area and a first wiring area. The first wiring area is located at a side of the display area. The display panel includes a substrate, a first partition structure, a second partition structure, a wiring layer, and a first conducting member. The first partition structure is disposed at a side of the substrate. The first partition structure defines a second opening. The second partition structure and the first partition structure are disposed in a same layer. The second partition structure is electrically insulated from the first partition structure. The second partition structure is also a first touch-control member. The wiring layer includes a first conducting line and a second conducting line. The first conducting line is electrically connected to the first partition structure. At least a portion of the first conducting line is located in the first wiring area. The second conducting line is electrically connected to the second partition structure. At least a portion of the second conducting line is located in the display area. At least a portion of the first conducting member is located in the first wiring area. The first conducting member and the second conducting line are electrically connected to each other and are located in different layers.

According to the display panel provided in the embodiment of the present application, the second partition structure and the first partition structure are disposed in the same layer and are electrically insulated from each other, and the second partition structure also functions as a first touch-control member, so that the first partition structure and the second partition structure can be prepared simultaneously. That is, the first partition structure 230 and the first touch-control member can be prepared simultaneously. As such, on the one hand, the number of layers in the touch-control module can be reduced, and the amount of masks used and the number of times of mask alignment can be reduced, which can reduce the chance of blocking of the second opening caused by mask alignment deviation, thereby improving the display effect of the display panel, with reduced production process and cost; on the other hand, the thickness of the display panel can be reduced, which facilitates obtaining a light and thin display panel.

In addition, the first trac is electrically connected to the first partition structure, and at least a portion of the first conducting line is located in the first wiring area. The second conducting line is electrically connected to the second partition structure, and at least a portion of the second conducting line is located in the display area. At least a portion of the first conducting member is located in the first wiring area, and the first conducting member and the second conducting line are electrically connected to each other and are disposed in different layers. As such, the second conducting line in the first wiring area can be replaced with the first conducting member to transmit the touch signal from the second conducting line.

On the one hand, it can effectively reduce the probability of interference between the first conducting line and the second conducting line in the first wiring area, thereby improving the display effect of the display panel. On the other hand, it can effectively mitigate occupation of the wiring space for the first conducting line in the first wiring area by the second conducting line, which ensures the layout space for the first conducting line in the first wiring area, thereby further improving the display effect of the display panel.

According to still another aspect of the present application, a display device is provided. The display device includes the display panel described in any one of the above embodiments.

### BRIEF DESCRIPTION OF THE DRAWINGS

FIG. 1 is a plan view of a display panel provided in an embodiment of the present application. FIG. 2 is a plan view of a display panel provided in another embodiment of the

present application.

FIG. 3 is a schematic structural top view of the display panel shown in FIG. 1.

FIG. 4 is a schematic structural partial view of the display panel shown in FIG. 3.

FIG. 5 is another schematic structural partial view of the display panel shown in FIG. 3.

FIG. 6 is yet another schematic structural partial view of the display panel shown in FIG. 3.

FIG. 7 is a schematic structural partial view of the display panel shown in FIG. 2.

FIG. 8 is another schematic structural partial view of the display panel shown in FIG. 2.

FIG. 9 is yet another schematic structural partial view of the display panel shown in FIG. 2.

FIG. 10 is a schematic structural view of a first touch-control member in the display panel shown in FIG. 1.

FIG. 11 is a schematic structural view of a first touch-control member and a second touch-control member in the display panel shown in FIG. 1.

FIG. 12 is a schematic structural cross-sectional view of an embodiment of the display panel shown in FIG. 1.

FIG. 13 is a schematic structural cross-sectional view of another embodiment of the display panel shown in FIG. 1.

FIG. 14 is a schematic structural cross-sectional view of yet another embodiment of the display panel shown in FIG. 1.

FIG. 15 is a schematic structural cross-sectional view of still another embodiment of the display panel shown in FIG. 1.

FIG. 16 is a schematic structural partial view of the display panel shown in FIG. 2.

FIG. 17 is a schematic structural view of a display device provided in an embodiment of the present application.

### REFERENCE SIGNS OF DRAWINGS

1. display device; 10. display panel; 10a. display area; 10b. first wiring area; 10c. bonding area; 10d. first wire-changing area; 10e. second wire-changing area; 10f. bending area; 11. substrate; 12. partition structure; 12a. partition sub-structure; 12a1. second opening; 12b. conductive connection portion; 12c. first opening; 121. first partition portion; 122. second partition portion; 13. wiring layer; 131. first conducting line; 132. second conducting line; 133. third conducting line; 134. fourth conducting line; 135. fifth conducting line; 136. sixth conducting line; 14. first touch-control member; 141. touch-control sub-electrode; 141a. sub-electrode unit; 141a1. first extension portion; 141a2. second extension portion; 142. first sub-electrode; 1411. third partition portion; 1412. fourth partition portion; 15. second touch-control member; 151. second sub-electrode; 161. first conducting member; 162. second conducting member; 163. third conducting member; 17. light-emitting unit; 171. first electrode; 172. light-emitting functional portion; 173. second electrode; 181. first insulating layer; 181a. third opening; 182. second insulating layer; 191. first through-hole connection structure; 192. second through-hole connection structure; 193. third through-hole connection structure; 194. fourth through-hole connection structure; 210. encapsulation structure; 211. first inorganic encapsulation layer; 212. organic encapsulation layer; 213. second inorganic encapsulation layer; 220. chip; 230. first partition structure; 240. second partition structure; 250. dam structure; 250a. dam; 251. first sub-layer; 252. second sub-layer; X. first direction; Y. second direction.

### DETAILED DESCRIPTION

The present application will be described in detail with reference to the accompanying drawings in order to facilitate understanding of the present application. The embodiments of the present application are provided in the drawings, but the present application can be implemented in many different forms and is not limited to the embodiments described herein. In contrast, these embodiments provided are only for thorough and comprehensive understanding of the contents of the present application.

Unless otherwise defined, all technical and scientific terms used herein have the same meaning as commonly understood by those of ordinary skill in the technical field to which the present application belongs. The terms used in the description of the present application are merely for the purpose of describing specific embodiments and are not intended to limit the present application. The term “and/or” used herein includes any and all combinations of one or more related listed items.

In describing positional relationships, unless otherwise specified, when an element, such as a layer, a film, or a substrate, is referred to as being “on” another element, it can be directly on the other element, or an intervening element can also be present. Further, when a layer is referred to as being “below” another layer, it can be directly below the other layer, or an intervening element can also be present. Furthermore, when a layer is referred to as being “between” two layers, it can be the only layer between the two layers, or another layer can also be present.

Unless explicitly using a limiting term such as “only”, “consisting of”, etc., in the case of using “including”, “having”, and “comprising”, another component can be added. Unless mentioned otherwise, a term in a singular form can include a plural form and should not be understood as being one in quantity.

It should be understood that the terms “first”, “second”, etc. herein can be used to describe various elements, but these elements should not be limited by these terms. These terms are only used to distinguish one element from another element. For example, without departing from the scope of the present application, a first element can be referred to as a second element and, similarly, a second element can also be referred to as a first element.

It should also be understood that in interpretation of an element, even if not explicitly described, the element is interpreted as including an error range, and the error range should be within an acceptable deviation range for a particular value determined by those skilled in the art. For example, “approximately”, “about”, or “substantially” can mean being within one or more standard deviations, which will not be limited herein.

Further, in the specification, the phrase “schematic plan view” refers to a drawing of a target portion viewed from the top. The phrase “schematic cross-sectional view” refers to a drawing of a vertically cut section of a target portion viewed from a side.

Additionally, the drawings are not drawn to a scale of 1:1, and relative dimensions of elements are drawn in the drawings by way of example only, and are not necessarily to a true scale.

Organic light-emitting diode (OLED) display devices have been seen as a promising display technology due to their advantages such as thinness, lightness, wide viewing angle, active light emission, continuously adjustable light color, low cost, fast response, low energy consumption, low driving voltage, wide operating temperature range, simple production process, high light emission efficiency, flexible display, etc.

In the related OLED display technology, in-cell type touch panels are display panels integrated with touch-control structures therein for realizing touch-control display. The in-cell type display panels have advantages of low production cost and thin thickness, rendering them to be gradually promoted and applied. However, the in-cell type display panels are prone to have display defects. The inventors discovered through research that the arrangement of touch-control lines in a frame area of a display panel reduces the space for drive lines, which makes it easy to generate interference between the touch-control lines and the drive lines, resulting in display defects of the display panel.

In view of the above technical issues, the present application provides a display panel and a display device for enhancing display effect of the display panel. The composition, preparation method, etc. of a partition structure described below can be referred to patent documents PCT/CN2023/134518, 202310759370.2, 202310740412.8, 202310707209.0, 202311346196.5 and 202310909421.5, the contents of which are hereby incorporated by reference.

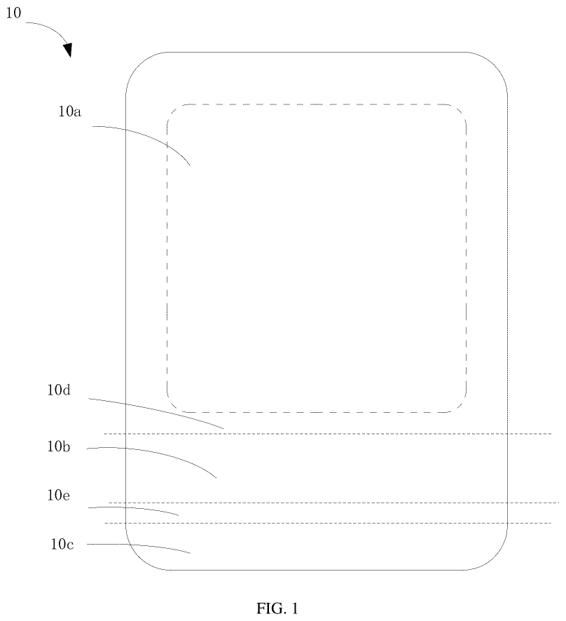

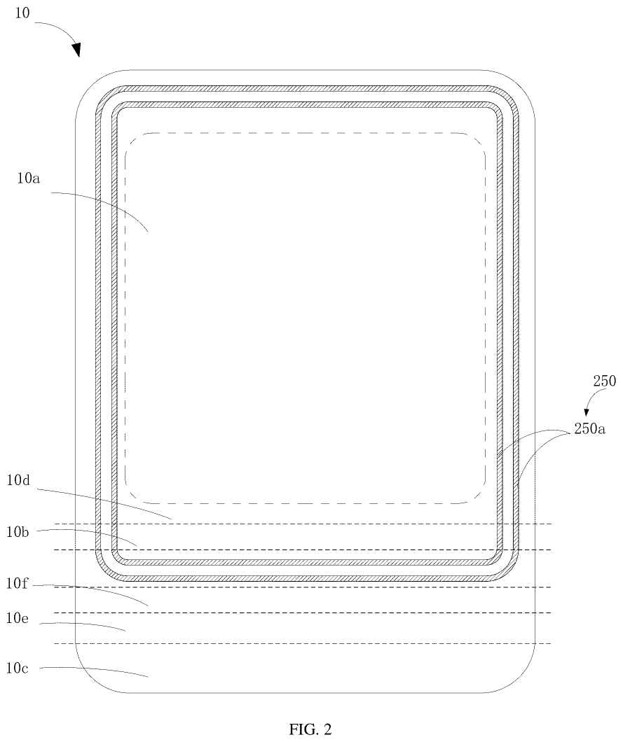

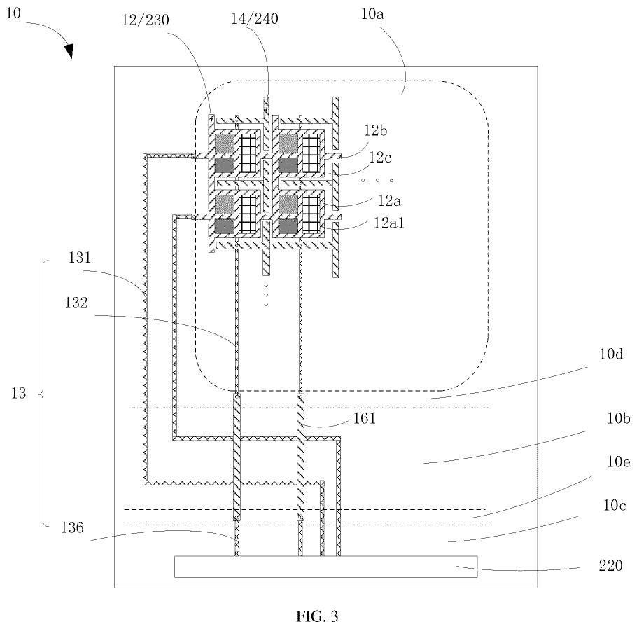

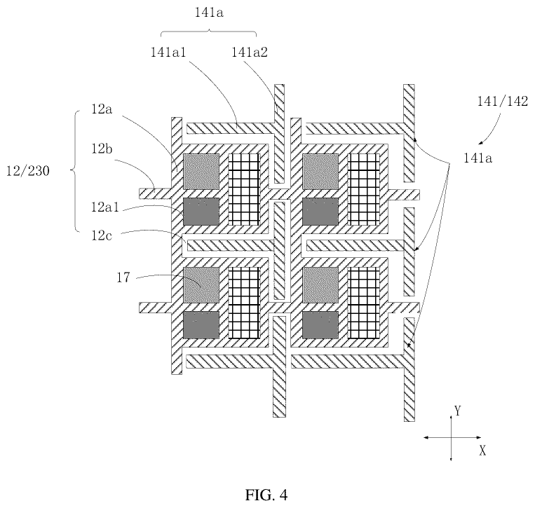

In a first aspect, referring to FIG. 1, FIG. 3 and FIG. 4, an embodiment of the present application provides a display panel 10. The display panel 10 includes a display area 10a and a first wiring area 10b. The first wiring area 10b is located at a side of the display area 10a. The display panel 10 includes a substrate 11, a partition structure 12, a first touch-control member 14, a wiring layer 13, and a first conducting member 161. The partition structure 12 is disposed at a side of the substrate 11. At least a portion of the partition structure 12 surrounds and defines a first opening 12c. At least a portion of the first touch-control member 14 is located in the first opening 12c. The first touch-control member 14 is electrically insulated from the partition structure 12. The wiring layer 13 includes a first conducting line 131 and a second conducting line 132. The first conducting line 131 is electrically connected to the partition structure 12. At least a portion of the first conducting line 131 is located in the first wiring area 10b. The second conducting line 132 is electrically connected to the first touch-control member 14. At least a portion of the second conducting line 132 is located in the display area 10a. At least a portion of the first conducting member 161 is located in the first wiring area 10b. The first conducting member 161 and the second conducting line 132 are electrically connected to each other and are respectively located in

Specifically, the display panel 10 can be an organic light-emitting diode (OLED) display panel 10, a quantum dot light-emitting diode (QLED) display panel 10, etc.

Referring to FIG. 1, the display panel 10 includes a display area 10a and a non-display area. The non-display area surrounds the display area 10a. A first wiring area 10b is located in the non-display area and is disposed at a side of the display area 10a.

The substrate 11 can be an array substrate. The substrate 11 can include a base and a driving circuit layer disposed on the base. The base can be rigid or flexible. When the base is rigid, the base can be a glass plate, a silicon wafer, etc. When the base is flexible, the base can be made of polyimide. The driving circuit layer includes a pixel driving circuit. The pixel driving circuit includes a thin-film transistor.

Referring to FIG. 3 and FIG. 4, a material of the partition structure 12 includes an electrically conductive material, which allows the first conducting line 131 to be electrically connected to the partition structure 12, so as to conveniently transmit a signal through the partition structure 12, thereby reducing conducting lines in the display area 10a. The first conducting line 131 can be configured to transmit a driving signal, which ensures normal operation of display function of the display panel 10. The second conducting line 132 is electrically connected to the first touch-control member 14. The second conducting line 132 can be configured to transmit a touch signal, which ensures the normal operation of touch function of the display panel 10.

Referring to FIG. 3, the wiring layer 13 includes the first conducting line 131 and the second conducting line 132. That is, the first conducting line 131 and the second conducting line 132 are disposed in the same layer. At least a portion of the first conducting line 131 is located in the first wiring area 10b. At least a portion of the second conducting line 132 is located in the display area 10a. At least a portion of the first conducting member 161 is located in the first wiring area 10b. The first conducting member 161 and the second conducting line 132 are electrically connected to each other and are located in different layers. As such, the second conducting line 132 in the first wiring area 10b can be replaced with the first conducting member 161 to transmit the touch signal from the second conducting line 132. Accordingly, it can effectively reduce the probability of interference between the first conducting line 131 and the second conducting line 132 in the first wiring area 10b, thereby improving the display effect of the display panel 10. In addition, at least a portion of the first conducting member 161 is located in the first wiring area 10b, at least a portion of the second conducting line 132 is located in the display area 10a, and the first conducting member 161 and the second conducting line 132 are located in different layers. That is, the first conducting member 161 and the first conducting line 131 are located in different layers. As such, it can effectively mitigate occupation of the wiring space for the first conducting line 131 in the first wiring area 10b by the second conducting line 132, which ensures the layout space for the first conducting line 131 in the first wiring area 10b, thereby ensuring the line width of the first conducting line 131 and further improving the display effect of the display panel 10.

Based on the above, according to the display panel 10 in the embodiment of the present application, the first conducting line 131 is electrically connected to the partition structure 12, and at least a portion of the first conducting line 131 is located in the first wiring area 10b. The second conducting line 132 is electrically connected to the first touch-control member 14, and at least a portion of the second conducting line 132 is located in the display area 10a. At least a portion of the first conducting member 161 is located in the first wiring area 10b. The first conducting member 161 and the second conducting line 132 are electrically connected to each other and are located in different layers. As such, the second conducting line 132 in the first wiring area 10b can be replaced with the first conducting member 161 to transmit a touch signal from the second conducting line 132. Accordingly, on the one hand, it can effectively reduce the probability of interference between the first conducting line 131 and the second conducting line 132 in the first wiring area 10b, thereby improving the display effect of the display panel 10. On the other hand, it can effectively mitigate occupation of the wiring space for the first conducting line 131 in the first wiring area 10b by the second conducting line 132, which ensures the layout space for the first conducting line 131 in the first wiring area 10b, thereby further improving the display effect of the display panel 10.

Referring to FIG. 3 and FIG. 4, in some embodiments, the partition structure 12 includes a plurality of partition sub-structures 12a. Adjacent partition sub-structures 12a are spaced to define the first opening 12c.

Thus, the electrical insulation between the first touch-control member 14 and the partition structure 12 can be guaranteed, which ensures the normal operation of both the display function and the touch function of the display panel 10.

Referring to FIG. 3 and FIG. 4, in some embodiments, each partition sub-structure 12a defines at least one second opening 12a1.

Referring to FIG. 4, in a specific embodiment, the display panel 10 further includes a light-emitting unit 17. The light-emitting unit 17 can be disposed in the second opening 12a1.

It can be understood that the “partition sub-structure 12a” refers to a structure that can partition the light-emitting materials of adjacent light-emitting units 17.

Referring to FIG. 3 and FIG. 4, in some embodiments, an orthographic projection of the partition sub-structure 12a on the substrate 11 has a grid shape.

Thus, the uniformity of the orthographic projection area of the partition sub-structure 12a on the substrate 11 can be improved, which reduces the difficulty of preparing the partition structure 12.

In some embodiments, the orthographic projection of the partition sub-structure 12a on the substrate 11 has a shape of a closed ring. In other words, the partition sub-structure 12a is an annular structure. For example, the partition sub-structure 12a can be an annular rectangle, an annular ring, an annular triangle, etc.

Thus, the partition sub-structure 12a can ensure a partition effect on an evaporation-deposited material, preventing a connection between the evaporation-deposited materials of adjacent light-emitting units 17, so as to avoid interference between the adjacent light-emitting units 17, thereby improving the display effect of the display panel 10.

Referring to FIG. 3 and FIG. 4, in some embodiments, the partition structure 12 includes conductive connection portions 12b. Adjacent partition sub-structures 12a can be electrically connected to each other through a conductive connection portion 12b. The conductive connection portion 12b is electrically insulated from the first touch-control member 14.

Thus, the plurality of partition sub-structures 12a on the entire surface can be electrically connected together through conductive connection portions 12b, which can decrease the electrical resistance of the first conducting line 131, so as to facilitate to reduce the power consumption of the display panel 10.

Referring to FIG. 3, in some embodiments, the first conducting member 161 and the partition structure 12 are disposed in a same layer and are electrically insulated from each other.

Thus, the first conducting member 161 and the partition structure 12 can be simultaneously formed, thereby reducing the number of masks that are used, and reducing the production cost of the display panel 10.

Referring to FIG. 3, in some embodiments, an orthographic projection of the first conducting member 161 on the substrate 11 overlaps with an orthographic projection of the first conducting line 131 on the substrate 11. The overlapping area is located in the first wiring area 10b.

Thus, the first conducting line 131 and the first conducting member 161 can be conveniently arranged, and interference between the first conducting member 161 and the first conducting line 131 can be prevented, thereby improving the display effect of the display panel 10.

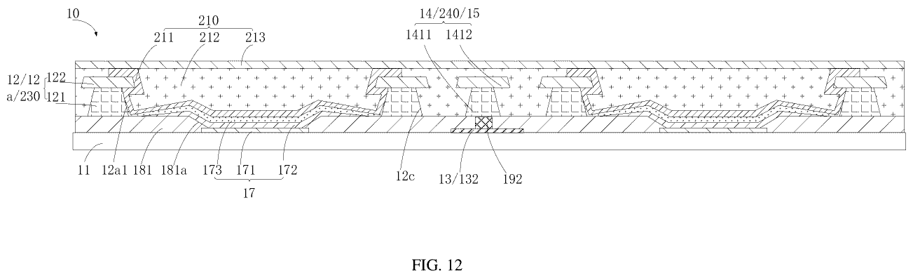

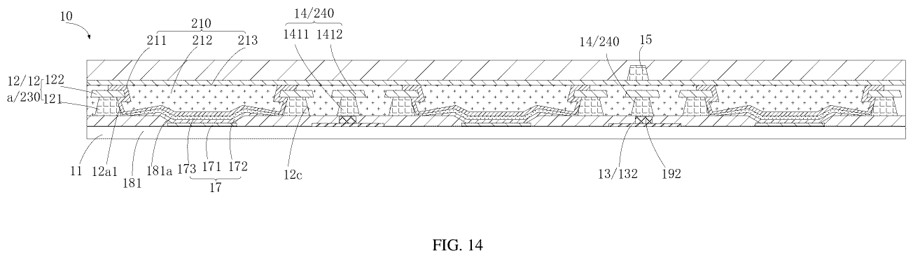

Referring to FIG. 12 and FIG. 14, in some embodiments, the wiring layer 13 is located in the substrate 11. In a specific embodiment, the substrate 11 can be an array substrate, and the wiring layer 13 is located in the array substrate.

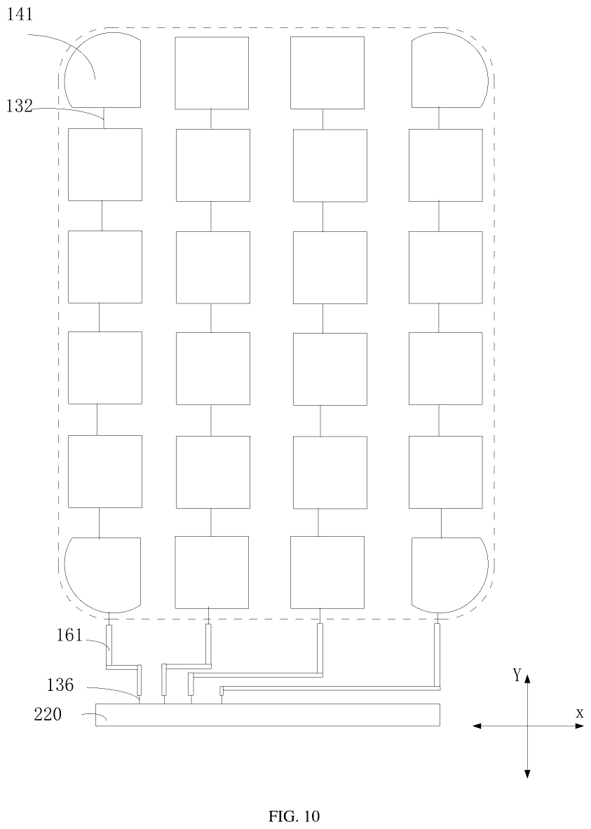

Referring to FIG. 4 and FIG. 10, in some embodiments, the first touch-control member 14 includes a plurality of touch-control sub-electrodes 141. The plurality of touch-control sub-electrodes 141 are spaced from each other and are disposed on a same side of the substrate 11.

Thus, the display panel 10 can be provided with a single touch-control layer (i.e., the first touch-control member 14) to achieve the touch-control function, which can reduce the thickness of the display panel 10. It should be noted that, in the embodiments of the present application, each touch-control sub-electrode 141 is both a driving electrode and a receiving electrode. The touch-control sub-electrode 141 can realize the touch function through the self-capacitance principle with the assistance of other metal layers in the display panel 10.

Referring to FIG. 4, in some embodiments, each touch-control sub-electrode 141 at least partially surrounds a periphery of at least one partition sub-structure 12a.

Thus, the area of the touch-control sub-electrodes 141 can be increased, thereby improving the touch-control accuracy.

Referring to FIG. 10, in some embodiments, the plurality of touch-control sub-electrodes 141 are disposed in rows along a first direction X and in columns along a second direction Y, and the second direction Y intersects with the first direction X.

Thus, the touch-control sub-electrodes 141 can be distributed relatively evenly, so as to obtain a relatively high touch-control accuracy of the display panel 10.

Referring to FIG. 4, in some embodiments, the touch-control sub-electrode 141 includes a plurality of sub-electrode units 141a. The plurality of sub-electrode units 141a are spaced from each other. The sub-electrode units 141a are electrically connected to the second conducting line 132.

Thus, the area of the touch-control sub-electrode 141 can be maximized, thereby improving the touch-control accuracy.

Referring to FIG. 4, in some embodiments, the conductive connection portion 12b is located between two adjacent sub-electrode units 141a.

Thus, the plurality of partition sub-structures 12a on the entire surface can be electrically connected together, and the electrical insulation between the partition sub-structures 12a and the first touch control portion 14 can be ensured.

Referring to FIG. 4, in some embodiments, each sub-electrode unit 141a includes a first extension portion 141a1 extending along the first direction X. The first extension portion 141a1 is located between two adjacent partition sub-structures 12a along the second direction Y. The first extension portion 141a1 is electrically connected to the second conducting line 132.

Thus, the area of each sub-electrode unit 141a can be increased, which increases the area of the touch-control sub-electrode 141, thereby improving the touch-control accuracy.

Referring to FIG. 4, in some embodiments, each sub-electrode unit 141a further includes a second extension portion 141a2 connected to the first extension portion 141a1. The second extension portion 141a2 extends along the second direction Y. The second extension portion 141a2 is located between two adjacent partition sub-structures 12a along the first direction X.

Thus, the area of the touch-control sub-electrode 141 can be maximized, thereby improving the touch-control accuracy. In addition, the uniformity of the area distribution of the touch-control sub-electrodes 141 can be improved, which facilitates the production of the touch-control sub-electrodes 141.

Referring to FIG. 3, in some embodiments, the second conducting line 132 extends along the second direction Y.

Thus, the second conducting line 132 can be conveniently electrically connected to the first touch-control member 14, thereby improving the touch-control sensitivity.

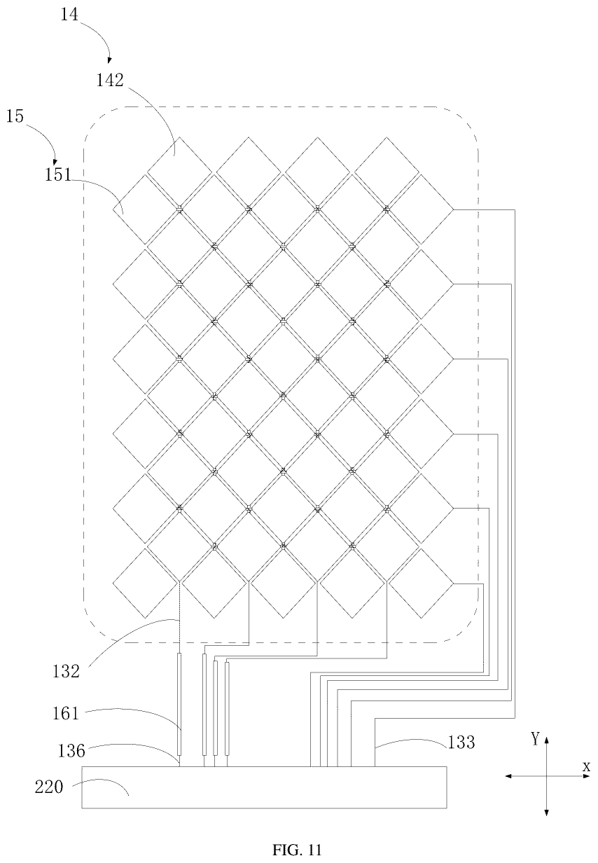

Referring to FIG. 11, in some embodiments, the display panel 10 further includes a second touch-control member 15. Either of the first touch-control member 14 and the second touch-control member 15 is configured to be an emitter electrode, and another of them is configured to be a receiver electrode.

Thus, the display panel 10 can have improved touch-control precision and accuracy.

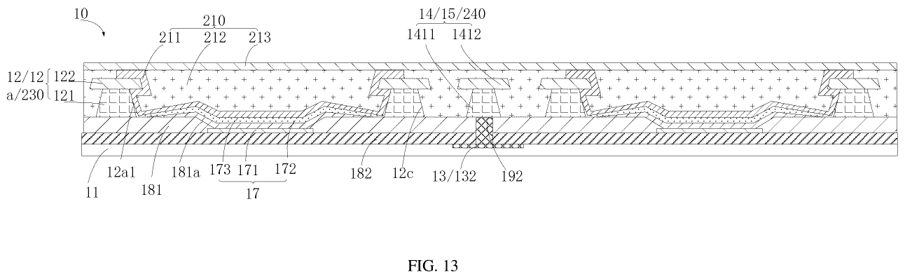

Referring to FIG. 12 and FIG. 13, in some embodiments, the second touch-control member 15 is located in the first opening 12c. The second touch-control member 15 is electrically insulated from the partition structure 12 and the first touch-control member 14. That is, the first touch-control member 14 and the second touch-control member 15 can be disposed in a same layer.

Thus, the thickness of the display panel 10 can be reduced, while the touch-control precision and accuracy of the display panel 10 can be improved.

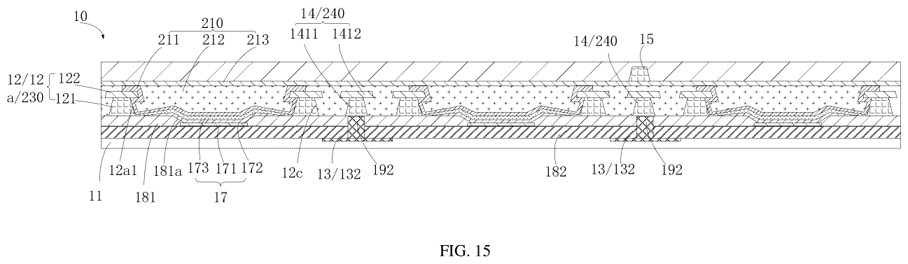

Referring to FIG. 14 and FIG. 15, in some embodiments, the second touch-control member 15 is located at a side of the first touch-control member 14 away from the substrate 11.

Thus, the display panel 10 can include two touch-control layers (i.e., the first touch-control member 14 and the second touch-control member 15), so as to increase the touch-control precision and accuracy of the display panel 10.

Referring to FIG. 12 to FIG. 15, in some embodiments, the display panel 10 further includes a first functional layer. The first functional layer is disposed at a side of the partition structure 12 away from the substrate 11. The second touch-control member 15 is disposed at a side of the first functional layer away from the substrate 11.

Thus, the first touch-control member 14 and the second touch-control member 15 can be insulated from each other.

Referring to FIG. 12 to FIG. 15, in a specific embodiment, the first functional layer includes an encapsulation structure 210. Specifically, the encapsulation structure 210 includes a first inorganic encapsulation layer 211, an organic encapsulation layer 212, and a second inorganic encapsulation layer 213 that are stacked one on another. The second touch-control member 15 can be disposed at a side of the second inorganic encapsulation layer 213 away from the substrate 11. Further, an insulating layer (not shown) can be disposed at a side of the second touch-control member 15 away from the substrate 11 to prevent the second touch-control member 15 from short-circuiting.

It can be understood that the first functional layer can be a color filter layer or a planarization layer. The embodiments of the present application do not limit the type of the first functional layer.

Referring to FIG. 11, in a specific embodiment, the first touch-control member 14 includes a plurality of first sub-electrodes 142. The plurality of first sub-electrodes 142 extend along the second direction Y and are spaced apart from each other along the first direction X. The second touch-control member 15 includes a plurality of second sub-electrodes 151. The plurality of second sub-electrodes 151 extend along the first direction X and are spaced apart from each other along the second direction Y. The first direction X intersects with the second direction Y.

Thus, a coupling area between the first sub-electrodes 142 and the second sub-electrodes 151 can be increased, which can effectively increase the capacitance signal variation amount when a finger touches, thereby effectively improving the touch sensitivity.

Referring to FIG. 11, in a specific embodiment, the wiring layer 13 further includes a third conducting line 133. The third conducting line 133 is electrically connected to the second touch-control member 15.

Thus, the touch-control function of the display panel 10 can be guaranteed to operate normally.

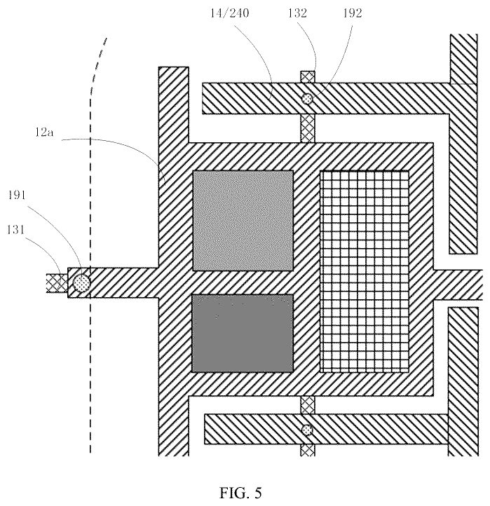

Referring to FIG. 5, in some embodiments, the display panel 10 further includes a first through-hole connection structure 191 and a second through-hole connection structure 192. The partition structure 12 is electrically connected to the first conducting line 131 via the first through-hole connection structure 191. The first touch-control member 14 is electrically connected to the second conducting line 132 via the second through-hole connection structure 192.

Thus, the partition structure 12 can be conveniently electrically connected to the first conducting line 131 via the first through-hole connection structure 191. The first touch-control member 14 can be conveniently electrically connected to the second conducting line 132 via the second through-hole connection structure 192.

Referring to FIG. 5, in a specific embodiment, the first through-hole connection structure 191 includes a first through-hole and a first conductive connection structure extending through the first through-hole. The first through-hole can extend through the layers between the partition structure 12 and the first conducting line 131 along the thickness direction of the substrate 11.

Referring to FIG. 5, in a specific embodiment, the second through-hole connection structure 192 includes a second through-hole and a second conductive connection structure extending through the second through-hole. The second through-hole can extend through the layers between the first touch-control member 14 and the second conducting line 132 along the thickness direction of the substrate 11.

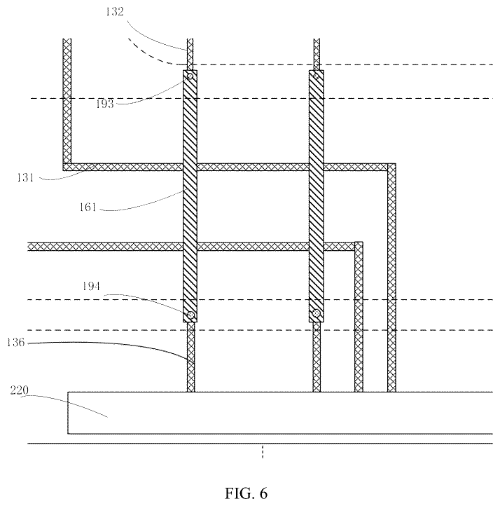

Referring to FIG. 6 to FIG. 9, in some embodiments, the display panel 10 further includes a first wire-changing area 10d. The first wire-changing area 10d is located between the display area 10a and the first wiring area 10b. The display panel 10 further includes a third through-hole connection structure 193, and the third through-hole connection structure 193 is located in the first wire-changing area 10d. The second conducting line 132 is electrically connected to the first conducting member 161 via the third through-hole connection structure 193.

The third through-hole connection structure 193 is located in the first wire-changing area 10d, and the second conducting line 132 is electrically connected to the first conducting member 161 via the third through-hole connection structure 193. In other words, the second conducting line 132 is changed to the first conducting member 161 in the first wire-changing area 10d. On the one hand, it can effectively reduce the probability of interference between the first conducting line 131 and the second conducting line 132 in the first wiring area 10b, thereby improving the display effect of the display panel 10. On the other hand, it can effectively mitigate occupation of the wiring space for the first conducting line 131 in the first wiring area 10b by the second conducting line 132, which ensures the layout space for the first conducting line 131 in the first wiring area 10b, thereby further improving the display effect of the display panel 10.

Referring to FIG. 6 to FIG. 9, in a specific embodiment, the third through-hole connection structure 193 includes a third through-hole and a third conductive connection structure extending through the third through-hole. The third through-hole can extend through the layers between the second conducting line 132 and the first conducting member 161 along the thickness direction of the substrate.

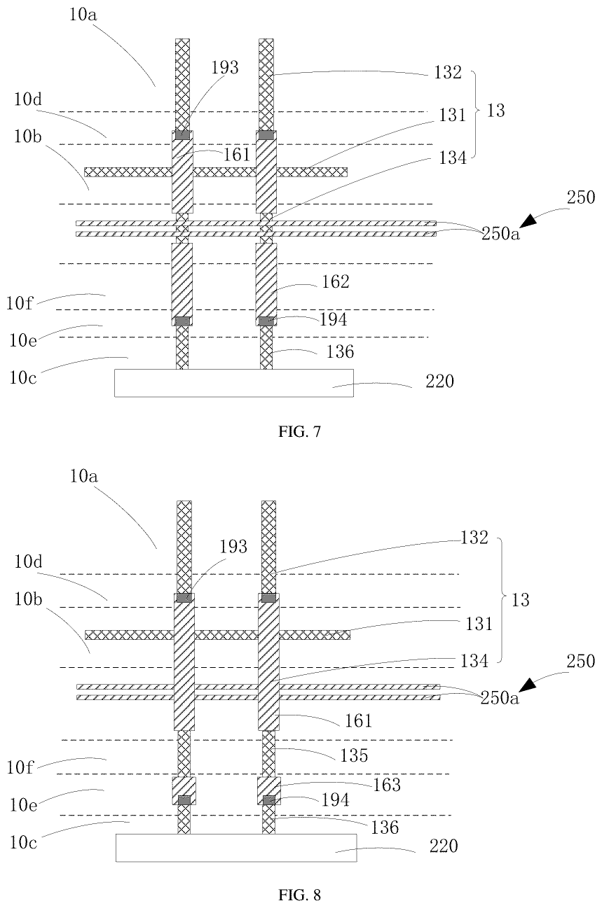

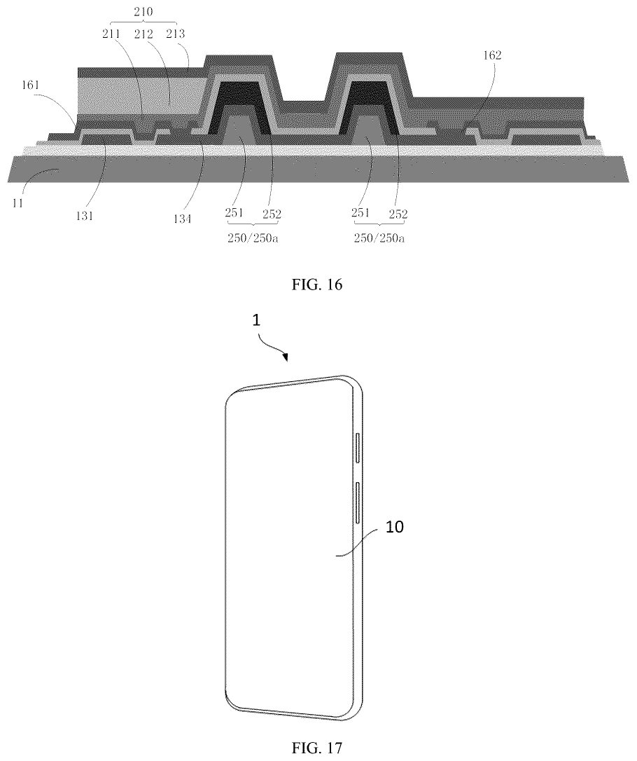

Referring to FIG. 7, FIG. 8 and FIG. 16, in some embodiments, the display panel 10 further includes a dam structure 250 and an encapsulation structure 210. The dam structure 250 is disposed at a side of the substrate 11. At least a portion of the dam structure 250 is disposed at a side of the first wiring area 10b away from the display area 10a. The encapsulation structure 210 covers the partition structure 12 and the first touch-control member 14. The encapsulation structure 210 includes an organic encapsulation layer 212. A boundary of the organic encapsulation layer 212 is located at a side of the dam structure 250 adjacent to the display area 10a.

Thus, by disposing the encapsulation structure 210, it can reduce the probability of failure or performance degradation of the light-emitting unit 17 and the first touch-control member 14 in the display panel 10 caused by infiltration of external water vapor and oxygen. The organic encapsulation layer 212 of the encapsulation structure 210 usually has a degree of fluidity. By disposing the dam structure 250, the boundary of the organic encapsulation layer 212 can be located at a side of the dam structure 250 adjacent to the display area 10a, so that the organic encapsulation layer 212 of the encapsulation structure 210 is blocked by the dam structure 250. As such, the organic encapsulation layer 212 can be prevented from overflowing to an undesirable area, and water vapor can be prevented from infiltration into the display area 10a, thereby improving the encapsulation reliability of the encapsulation structure 210, and further enhancing the reliability of the display panel 10.

Referring to FIG. 2, in some embodiments, the dam structure 250 surrounds the display area 10a. In a specific embodiment, the dam structure 250 can include at least two dams 250a spaced apart from each other in a direction from the display area 10a towards the non-display area. The dam 250a can be an annular structure. The dam 250a surrounds the display area 10a.

Thus, the encapsulation reliability of the encapsulation structure 210 can be enhanced, thereby further improving the reliability of the display panel 10.

Referring to FIG. 16, in some embodiments, the encapsulation structure 210

further includes a first inorganic encapsulation layer 211 and a second inorganic encapsulation layer 213. The first inorganic encapsulation layer 211 is located at a side of the organic encapsulation layer 212 adjacent to the substrate 11. The second inorganic encapsulation layer 213 is located at a side of the organic encapsulation layer 212 away from the substrate 11. The first inorganic encapsulation layer 211 and the second inorganic encapsulation layer 213 cover the dam structure 250.

Compared with organic materials, inorganic materials have a better blocking effect on water vapor. In the present embodiment, the first inorganic encapsulation layer 211 is disposed at a side of the organic encapsulation layer 212 adjacent to the substrate 11. The second inorganic encapsulation layer 213 is disposed at a side of the organic encapsulation layer 212 away from the substrate 11. The first inorganic encapsulation layer 211 and the second inorganic encapsulation layer 213 cover the dam structure 250. That is, the dam structure 250 and the side surface of the dam structure 250 away from the display area 10a are encapsulated by both the first inorganic encapsulation layer 211 and the second inorganic encapsulation layer 213. Therefore, the display area 10a can be prevented from water vapor intrusion, so as to effectively improve the encapsulation reliability of the encapsulation structure 210, and further enhance the reliability of the display panel 10.

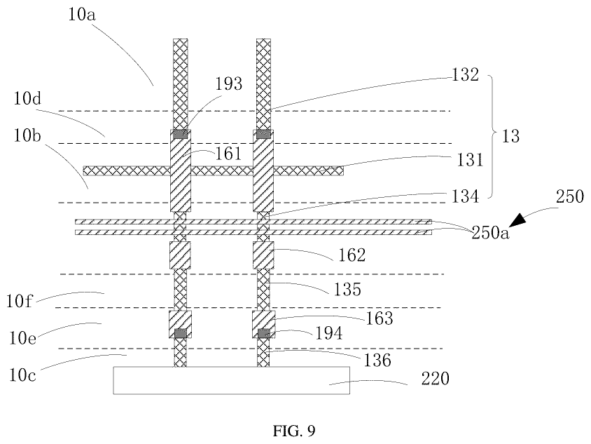

Referring to FIG. 7 and FIG. 9, in some embodiments, the wiring layer 13 further includes a fourth conducting line 134. An orthographic projection of the fourth conducting line 134 on the substrate 11 overlaps with an orthographic projection of the dam structure 250 on the substrate 11. The first conducting member 161 extends to the side of the dam structure 250 adjacent to the display area 10a and is electrically connected to the fourth conducting line 134.

Thus, the first conducting member 161 extends to the side of the dam structure 250 adjacent to the display area 10a and is electrically connected to the fourth conducting line 134. In other words, the first conducting member 161 is changed to the fourth conducting line 134 at the side of the dam structure 250 adjacent to the display area 10a. As such, the first conducting member 161 can cross over the dam structure 250, so as to be prevented from breaking due to climbing the dam structure 250, thereby improving the stability of touch signal transmission.

Referring to FIG. 7 and FIG. 9, in some embodiments, the display panel 10 further includes a second conducting member 162. The second conducting member 162 is located at a side of the dam structure 250 away from the display area 10a. The second conducting member 162 and the fourth conducting line 134 are electrically connected to each other and are located in different layers.

Thus, the fourth conducting line 134 can be replaced with the second conducting member 162 at the side of the dam structure 250 away from the display area 10a. The second conducting member 162 and the fourth conducting line 134 are located in different layers. That is, the second conducting member 162 and the first conducting line 131 are located in different layers. As such, on the one hand, it can effectively reduce the probability of interference, at the side of the dam structure 250 away from the display area 10a, between the fourth conducting line 134 and the first conducting line 131, thereby improving the display effect of the display panel 10. On the other hand, it can effectively mitigate occupation of the wiring space for the first conducting line 131 by the fourth conducting line 134, which ensures the line width of the first conducting line 131, thereby further improving the display effect of the display panel 10.

In some embodiments, the second conducting member 162 and the first conducting member 161 are disposed in a same layer.

Thus, the first conducting member 161 and the second conducting member 162

can be prepared simultaneously, thereby decreasing the number of masks that are used, and reducing the production cost of the display panel 10.

Referring to FIG. 15, in some embodiments, the dam structure 250 includes a first sub-layer 251 and a second sub-layer 252. The first sub-layer 251 is located at a side of the fourth conducting line 134 adjacent to the substrate 11. The second sub-layer 252 is located at a side of the fourth conducting line 134 away from the substrate 11.

Thus, the first sub-layer 251 can separate the fourth conducting line 134 from the layers located at a side of the fourth conducting line 134 adjacent to the substrate 11. The second sub-layer 252 can separate the fourth conducting line 134 from the layers located at a side of the fourth conducting line 134 away from the substrate 11. As such, the fourth conducting line 134 can be electrically insulated from the layers located at the side of the fourth conducting line 134 adjacent to the substrate 11, and electrically from the layers located at the side of the fourth conducting line 134 away from the substrate 11, which is beneficial to improving the display effect and touch-control effect of the display panel 10.

In a specific embodiment, the first sub-layer 251 and the second sub-layer 252 can be made of an organic material, such as an organic adhesive.

Referring to FIG. 15, in some embodiments, an orthographic projection of the fourth conducting line 134 on the substrate 11 covers the orthographic projection of the dam structure 250 on the substrate 11.

Thus, the fourth conducting line 134 can be conveniently electrically connected to the first conducting member 161 at the side of the dam structure 250 adjacent to the display area 10a, and the fourth conducting line 134 can be conveniently electrically connected to the second conducting member 162 at the side of the dam structure 250 away from the display area 10a. As such, the first conducting member 161 is prevented from breaking due to climbing the dam structure 250, thereby improving the stability of touch signal transmission and the touch-control performance of the display panel 10. In addition, the restriction by the fourth conducting line 134 on the layout and line width of the first conducting line 131 can be minimized as much as possible, thereby further improving the display effect of the display panel 10.

Referring to FIG. 8, in some embodiments, the display panel 10 further includes a bending area 10f. The bending area 10f is located at a side of the dam structure 250 away from the display area 10a. The wiring layer 13 further includes a fifth conducting line 135. At least a portion of the fifth conducting line 135 is located in the bending area 10f. The first conducting member 161 extends to a side of the bending area 10f adjacent to the display area 10a and is electrically connected to the fifth conducting line 135.

Thus, the first conducting member 161 crosses the bending area 10f through the fifth conducting line 135, which prevents the first conducting member 161 from extending through the bending area 10f causing the reduction of bending performance of the bending area 10f.

Referring to FIG. 8, in some embodiments, the display panel 10 further includes a third conducting member 163. The third conducting member 163 is located at a side of the bending area 10f away from the display area 10a. The third conducting member 163 and the fifth conducting line 135 are electrically connected to each other and are located in different layers.

Thus, the fifth conducting line 135 can be replaced with the third conducting member 163 at the side of the bending area 10f away from the display area 10a. The third conducting member 163 and the fifth conducting line 135 are located in different layers, that is, the third conducting member 163 and the first conducting line 131 are located in different layers. As such, on the one hand, it can effectively reduce the probability of interference between the fifth conducting line 135 and the first conducting line 131 at the side of the bending area 10f away from the display area 10a, thereby improving the display effect of the display panel 10. On the other hand, it can effectively mitigate occupation of the wiring space for the first conducting line 131 by the fifth conducting line 135, which ensures the line width of the first conducting line 131, thereby improving the display effect of the display panel 10.

In some embodiments, the third conducting member 163 and the first conducting member 161 are disposed in a same layer.

Thus, the first conducting member 161 and the third conducting member 163 can be prepared simultaneously, thereby decreasing the number of masks that are used, and reducing the production cost of the display panel 10.

Referring to FIG. 6 to FIG. 9, in some embodiments, the display panel 10 further includes a bonding area 10c. The bonding area 10c is located at a side of the dam structure 250 away from the display area 10a. A chip 220 is disposed in the bonding area 10c. The chip 220 is electrically connected to the first conducting line 131 and the first conducting member 161.

Thus, the display function and the touch-control function are ensured to be in a normal state.

Referring to FIG. 6 to FIG. 9, in some embodiments, the wiring layer 13 further includes a sixth conducting line 136. At least a portion of the sixth conducting line 136 is located in the bonding area 10c. The sixth conducting line 136 is electrically connected to the chip 220 and the first conducting member 161.

Thus, the first conducting member 161 can be electrically connected to the bonding area 10c through the sixth wiring 136, so as to be electrically connected to the chip 220 in the bonding area 10c.

Referring to FIG. 6 and FIG. 7, in some embodiments, the display panel 10 further includes a second wire-changing area 10e. The second wire-changing area 10e is located at a side of the bonding area 10c adjacent to the display area 10a. The display panel 10 further includes a fourth through-hole connection structure 194, and the fourth through-hole connection structure 194 is located in the second wire-changing area 10e. The sixth conducting line 136 extends to the second wire-changing area 10e. The sixth conducting line 136 is electrically connected to the first conducting member 161 through the fourth through-hole connection structure 194.

Thus, the second conducting line 132 and the sixth conducting line 136 both cross the first wiring area 10b. As such, on the one hand, it can effectively reduce the probability of interference between the first conducting line 131 and the second conducting line 132 and the probability of interference between the first conducting line 131 and the sixth conducting line 136 in the first wiring area 10b, thereby improving the display effect of the display panel 10. On the other hand, it can effectively mitigate occupation of the wiring space for the first conducting line 131 in the first wiring area 10b by the second conducting line 132 and the sixth conducting line 136, which ensures the layout space for the first conducting line 131 in the first wiring area 10b, thereby improving the display effect of the display panel 10.

Referring to FIG. 6, in a specific embodiment, the fourth through-hole connection structure 194 includes a fourth through-hole and a fourth conductive connection structure extending through the fourth through-hole. The fourth through-hole can extend through the layers between the sixth conducting line 136 and the first conducting member 161 along the thickness direction of the substrate 11.

Referring to FIG. 12 to FIG. 15, in some embodiments, the partition structure 12 further includes a first partition portion 121 and a second partition portion 122. The second partition portion 122 is disposed at a side of the first partition portion 121 away from the substrate 11. An orthographic projection of the first partition portion 121 on the substrate 11 falls within an orthographic projection of the second partition portion 122 on the substrate 11. The second conducting line 132 is electrically connected to the first partition portion 121.

Thus, the partition structure 12 can be made into an undercut structure with a large upper portion and a small lower portion, which ensures a better partition performance of the partition structure 12. In addition, by disposing the first partition portion 121 under the second partition portion 122, the first conducting member is conveniently electrically connected to other layers.

In a specific embodiment, the first partition portion 121 includes at least one metal layer.

In an embodiment, a material of the metal layer includes at least one of a metal or a metal oxide. For example, the metal can be selected from silver, copper, titanium, aluminum, etc. The metal oxide can be selected from tin oxide, zinc oxide, cadmium oxide, indium oxide, indium tin oxide, zinc indium oxide, zinc gallium oxide, zinc aluminum oxide, titanium tantalum oxide, etc.

In another embodiment, the first partition portion 121 can include a first metal layer (not shown) and a second metal layer (not shown) stacked in a direction away from the substrate 11. An outer contour of an orthographic projection of the first metal layer on the substrate 11 is located outside an outer contour of an orthographic projection of the second metal layer on the substrate 11. The first metal layer and the second metal layer are stacked in sequence in a direction away from the substrate 11. In one example, a material of the first metal layer can be Mo, and a material of the second metal layer can be Al.

In some embodiments, a material of the second partition portion 122 includes an electrically insulating material.

Thus, the second partition portion 122 can have an insulating function, which prevents an electrical contact between the first conducting member 161 and the layers above the partition structure 12, thereby avoiding a short circuit.

In some embodiments, a material of the second partition portion 122 includes an electrically conductive material. For example, the material of the second partition portion 122 can be a metal conductive material, such as silver, copper, titanium, aluminum, etc.

Thus, the strength and hardness of the second partition portion 122 can be enhanced, which makes the second partition portion 122 not easy to collapse during the formation of the partition structure, and ensures the relationship between the projections of second partition portion 122 and the first conducting member 161 on the substrate 11, thereby facilitating to obtain a partition structure with a desired shape. In addition, the electrical resistance of the first conducting line 131 can be reduced, which facilitates to reduce the power consumption of the display panel 10.

Referring to FIG. 12 to FIG. 15, in some embodiments, the first touch-control member 14 includes a third partition portion 1411. The third partition portion 1411 and the first partition portion 121 are disposed in a same layer and are electrically insulated from each other.

Thus, the partition structure 12 and the first touch-control member 14 can be prepared simultaneously, thereby decreasing the number of masks that are used, and reducing the production cost of the display panel 10.

Referring to FIG. 12 to FIG. 15, in some embodiments, the first touch-control member 14 further includes a fourth partition portion 1412. The fourth partition portion 1412 is disposed at a side of the third partition portion 1411 away from the substrate 11. The fourth partition portion 1412 and the second partition portion 122 are disposed in a same layer and are electrically insulated from each other.

Thus, the partition structure 12 and the first touch-control member 14 can be prepared simultaneously, thereby decreasing the number of masks that are used, and reducing the production cost of the display panel 10.

Referring to FIG. 12 to FIG. 15, in some embodiments, an orthographic projection of the third partition portion 1411 on the substrate 11 falls within an orthographic projection of the fourth partition portion 1412 on the substrate 11.

Thus, the third partition portion 1411 and the fourth partition portion 1412 together form a partition wall. On the one hand, the formed partition wall has an undercut structure with a large upper portion and a small lower portion, which ensures a better partition performance of the partition wall. On the other hand, referring to FIG. 3, both the partition structure 12, and the partition wall formed with the third partition portion 1411 and the fourth partition portion 1412, are disposed between two adjacent light-emitting units 17. As such, the two adjacent light-emitting units 17 are separated by multiple partition materials, which further alleviates the inter-pixel leakage between adjacent light-emitting units 17.

Referring to FIG. 12 to FIG. 15, in some embodiments, the display panel 10 further includes a light-emitting functional portion 172. The light-emitting functional portion 172 is disposed in the second opening 12a1. The light-emitting functional portion 172 is spaced from the partition sub-structure 12a.

Thus, the layers of the light-emitting functional portions 172 with different colors can be insulated from each other, which prevents the current interference between two adjacent light-emitting functional portions 172, and ensures that when a light-emitting functional portion 172 with a certain color is in the light emission state, no current can be transmitted laterally to the adjacent light-emitting functional portion 172, thereby preventing the color interference of the display panel 10 and enhancing the display effect.

It can be understood that the light-emitting functional portion 172 includes at least an emission layer (EML), and can further include one or more of a hole injection layer (HIL), a hole transport layer (HTL), an electron injection layer (EIL), an electron transport layer (ETL), a hole block layer (HBL), and an electron block layer (EBL). Alternatively, the light-emitting functional portion 172 can be a laminated light-emitting layer, which includes at least two light-emitting layers and a charge generation layer (CGL) located between the two adjacent light-emitting layers.

Referring to FIG. 12 to FIG. 15, in some embodiments, the display panel 10 further includes a first electrode 171. The first electrode 171 is located at a side of the light-emitting functional portion 172 adjacent to the substrate 11. The first electrode 171 is electrically insulated from the partition structure 12.

Referring to FIG. 12 to FIG. 15, in some embodiments, the display panel 10 further includes a second electrode 173. The second electrode 173 is located at a side of the light-emitting functional portion 172 away from the substrate 11. The second electrode 173 is electrically connected to the partition sub-structure 12a.

Thus, by electrically connecting the second electrode 173 to the partition structure 12, the partition structure 12 can conduct a power signal, which reduces the conducting line in the display area 10a of the display panel 10.

It should be noted that the first electrode 171, the light-emitting functional portion 172, and the second electrode 173 together form the light-emitting unit 17. The first electrode 171 can be an anode, and the second electrode 173 can be a cathode. The first electrode 171 and the second electrode 173 are both electrically connected to the pixel driving circuit.

Referring to FIG. 12 to FIG. 15, in some embodiments, the display panel 10 further includes a first insulating layer 181. The first insulating layer 181 is disposed between the partition structure 12 and the first electrode 171. The first insulating layer 181 defines a third opening 181a. The third opening 181a is located corresponding to the second opening 12a1. At least a portion of the light-emitting functional portion 172 is disposed in the third opening 181a. The third opening 181a exposes the first electrode 171.

Thus, the first electrode 171 can be insulated from the partition structure 12 and from an adjacent first electrode 171.

Referring to FIG. 12 to FIG. 15, in some embodiments, the orthographic projection of the partition sub-structure 12a on the substrate 11 is located at a periphery of an orthographic projection of the third opening 181a on the substrate 11.

Thus, the light emission angle of the light-emitting functional portion 172 will not be restricted by the partition sub-structure 12a.

In a specific embodiment, the first insulating layer 181 can be a pixel definition layer (PDL), or other insulating layers.

In another specific embodiment, a material of the first insulating layer 181 includes an inorganic material, such as silicon oxide, silicon nitride, etc.

Thus, the first insulating layer 181 can block the infiltration of water vapor and oxygen, thereby enhancing the reliability of the display panel 10.

Referring to FIG. 12 and FIG. 14, in some embodiments, the first electrode 171 and the wiring layer 13 are disposed in a same layer and are electrically insulated from each other.

Thus, the first electrode 171 and the wiring layer 13 can be prepared in the same process. That is, the first electrode 171 and the wiring layer 13 can be prepared simultaneously, thereby decreasing the number of masks that are used, and reducing the production cost of the display panel 10.

Referring to FIG. 13 and FIG. 15, in some embodiments, the wiring layer 13 is located at a side of the first electrode 171 adjacent to the substrate 11. The wiring layer 13 is electrically insulated from the first electrode 171. That is, the wiring layer 13 and the first electrode 171 are disposed in different layers.

Thus, arrangement of the first electrode 171, the first conducting line 131, and the second conducting line 132 can be facilitated.

Referring to FIG. 13 and FIG. 15, in some embodiments, the display panel 10 further includes a second insulating layer 182. The second insulating layer 182 is disposed between the wiring layer 13 and the first electrode 171.

Thus, the wiring layer 13 and the first electrode 171 can be electrically insulated from each other.

In a specific embodiment, a material of the second insulating layer 182 can be an organic material, such as an organic adhesive.

In a second aspect, referring to FIG. 1, FIG. 3 and FIG. 4, an embodiment of the present application provides a display panel 10. The display panel 10 includes a display area 10a and a first wiring area 10b. The first wiring area 10b is located at a side of the display area 10a. The display panel 10 includes a substrate 11, a first partition structure 230, a second partition structure 240, a wiring layer 13, and a first conducting member 161. The first partition structure 230 is disposed at a side of the substrate 11. The first partition structure 230 defines a second opening 12a1. The second partition structure 240 and the first partition structure 230 are disposed in a same layer. The second partition structure 240 is electrically insulated from the first partition structure 230. The second partition structure 240 is also a first touch-control member 14. The wiring layer 13 includes a first conducting line 131 and a second conducting line 132. The first conducting line 131 is electrically connected to the first partition structure 230. At least a portion of the first conducting line 131 is located in the first wiring area 10b. The second conducting line 132 is electrically connected to the second partition structure 240. At least a portion of the second conducting line 132 is located in the display area 10a. At least a portion of the first conducting member 161 is located in the first wiring area 10b. The first conducting member 161 and the second conducting line 132 are electrically connected to each other and are located in different layers.

According to the display panel 10 provided in the embodiment of the present application, the second partition structure 240 and the first partition structure 230 are disposed in the same layer and are electrically insulated from each other, and the second partition structure 240 also functions as a first touch-control member 14, so that the first partition structure 230 and the second partition structure 240 can be prepared simultaneously. That is, the first partition structure 230 and the first touch-control member 14 can be prepared simultaneously. As such, on the one hand, the number of layers in the touch-control module can be reduced, and the amount of masks used and the number of times of mask alignment can be reduced, which can reduce the chance of blocking of the second opening 12a1 caused by mask alignment deviation, so as to improve the display effect of the display panel 10, with reduced production process and cost; on the other hand, the thickness of the display panel 10 can be reduced, which facilitates obtaining a light and thin display panel 10.

In addition, the first conducting line 131 is electrically connected to the first partition structure 230, and at least a portion of the first conducting line 131 is located in the first wiring area 10b. The second conducting line 132 is electrically connected to the second partition structure 240, and at least a portion of the second conducting line 132 is located in the display area 10a. At least a portion of the first conducting member 161 is located in the first wiring area 10b, and the first conducting member 161 and the second conducting line 132 are electrically connected to each other and are disposed in different layers. As such, the second conducting line 132 can be replaced with the first conducting member 161 in the first wiring area 10b to transmit the touch signal from the second conducting line 132. On the one hand, it can effectively reduce the probability of interference between the first conducting line 131 and the second conducting line 132 in the first wiring area 10b, thereby improving the display effect of the display panel 10. On the other hand, it can effectively mitigate occupation of the wiring space for the first conducting line 131 in the first wiring area 10b by the second conducting line 132, which ensures the layout space for the first conducting line 131 in the first wiring area 10b, thereby improving the display effect of the display panel 10.

In a third aspect, referring to FIG. 17, an embodiment of the present application further provides a display device 1. The display device 1 includes the display panel 10 in any one of the above embodiments. Therefore, the display effect of the display device 1 can be improved.

The display device 1 can be a laptop computer, a mobile phone, a wireless device, a personal digital assistant (PDA), a handheld or portable computer, a GPS receiver/navigator, a camera, an MP4 video player, a camcorder, a game console, a watch, a clock, a calculator, a television monitor, a flat-panel display, a computer monitor, a car display (e.g., an odometer display, etc.), a navigator, a cockpit controller and/or display, a display of a camera view (e.g., a display of a rearview camera in a vehicle), an electronic photo, an electronic billboard or sign, a projector, etc.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above-described embodiments are only several implementations of the present disclosure, and the descriptions are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be defined by the appended claims.

What is claimed is:

1. A display panel, comprising:
a display area;
a first wiring area located at a side of the display area;
a substrate;
a partition structure disposed at a side of the substrate, at least a portion of the partition structure surrounding and defining a first opening;
a first touch-control member, at least a portion of the first touch-control member being located in the first opening, the first touch-control member being insulated from the partition structure;
a wiring layer comprising a first conducting line and a second conducting line, the first conducting line being electrically connected to the partition structure, at least a portion of the first conducting line being located in the first wiring area, the second conducting line being electrically connected to the first touch-control member, and at least a portion of the second conducting line being located in the display area; and
a first conducting member, at least a portion of the first conducting member being located in the first wiring area, and the first conducting member and the second conducting line being electrically connected to each other and being respectively located in different layers.

2. The display panel according to claim 1, wherein the partition structure comprises a plurality of partition sub-structures, and adjacent partition sub-structures are spaced from each other to define the first opening;
each partition sub-structure defines at least one second opening;
an orthographic projection of each partition sub-structure on the substrate has a grid shape, or an orthographic projection of each partition sub-structure on the substrate has a shape of a closed ring;
the partition structure comprises a conductive connection portion; adjacent partition sub-structures are electrically connected to each other through the conductive connection portion, and the conductive connection portion is electrically insulated from the first touch-control member;
the first conducting member and the partition structure are disposed in a same layer and are electrically insulated from each other;
an orthographic projection of the first conducting member on the substrate overlaps with an orthographic projection of the first conducting line on the substrate, forming an overlapping area located in the first wiring area;
the wiring layer is located in the substrate.

3. The display panel according to claim 2, wherein the first touch-control member comprises a plurality of touch-control sub-electrodes; and the plurality of touch-control sub-electrodes are spaced from each other and disposed on a same side of the substrate;
each touch-control sub-electrode at least partially surrounds a periphery of at least one partition sub-structure;
the plurality of touch-control sub-electrodes are disposed in rows along a first direction and in columns along a second direction, and the second direction intersects with the first direction.

4. The display panel according to claim 3, wherein each touch-control sub-electrode comprises a plurality of sub-electrode units, the plurality of sub-electrode units are spaced from each other, and the sub-electrode units are electrically connected to the second conducting line;
the conductive connection portion is located between two adjacent sub-electrode units;
each sub-electrode unit comprises a first extension portion extending along the first direction, the first extension portion is located between two adjacent partition sub-structures along the second direction, and the first extension portion is electrically connected to the second conducting line;
each sub-electrode unit further comprises a second extension portion connected to the first extension portion, the second extension portion extends along the second direction, and the second extension portion is located between two adjacent partition sub-structures along the first direction;
the second conducting line extends along the second direction.

5. The display panel according to claim 1, further comprising a second touch-control member;
wherein one of the first touch-control member and the second touch-control member is configured to be an emitter electrode, and the other is configured to be a receiver electrode;
wherein
the second touch-control member is located in the first opening, and the second touch-control member is electrically insulated from the partition structure and the first touch-control member; or
the second touch-control member is located at a side of the first touch-control member away from the substrate; or
the display panel further comprises a first functional layer, the first functional layer is disposed at a side of the partition structure away from the substrate, and the second touch-control member is disposed at a side of the first functional layer away from the substrate; and
wherein
the first touch-control member comprises a plurality of first sub-electrodes, the plurality of first sub-electrodes extend along the second direction and are spaced apart from each other along the first direction, the second touch-control member comprises a plurality of second sub-electrodes, the plurality of second sub-electrodes extend along the first direction and are spaced apart from each other along the second direction, and the first direction intersects with the second direction;
the wiring layer further comprises a third conducting line, and the third conducting line is electrically connected to the second touch-control member.

6. The display panel according to claim 1, further comprising a first through-hole connection structure and a second through-hole connection structure, wherein the partition structure is electrically connected to the first conducting line via the first through-hole connection structure, and the first touch-control member is electrically connected to the second conducting line via the second through-hole connection structure.

7. The display panel according to claim 6, further comprising a first wire-changing area and a third through-hole connection structure, wherein the first wire-changing area is located between the display area and the first wiring area, the third through-hole connection structure is located in the first wire-changing area, and the second conducting line is electrically connected to the first conducting member via the third through-hole connection structure.

8. The display panel according to claim 6, further comprising a dam structure and an encapsulation structure, wherein the dam structure is disposed at a side of the substrate, at least a portion of the dam structure is disposed at a side of the first wiring area away from the display area, the encapsulation structure covers the partition structure and the first touch-control member, the encapsulation structure comprises an organic encapsulation layer, and a boundary of the organic encapsulation layer is located at a side of the dam structure adjacent to the display area;
the dam structure surrounds the display area;
the encapsulation structure further comprises a first inorganic encapsulation layer and a second inorganic encapsulation layer, the first inorganic encapsulation layer is located at a side of the organic encapsulation layer adjacent to the substrate, the second inorganic encapsulation layer is located at a side of the organic encapsulation layer away from the substrate, and the first inorganic encapsulation layer and the second inorganic encapsulation layer cover the dam structure.

9. The display panel according to claim 8, wherein the wiring layer further comprises a fourth conducting line, an orthographic projection of the fourth conducting line on the substrate overlaps with an orthographic projection of the dam structure on the substrate, and the first conducting member extends to a side of the dam structure adjacent to the display area and is electrically connected to the fourth conducting line;
the display panel further comprises a second conducting member, the second conducting member is located at a side of the dam structure away from the display area, and the second conducting member and the fourth conducting line are electrically connected to each other and are located in different layers;
the second conducting member and the first conducting member are disposed in a same layer;
the dam structure comprises a first sub-layer and a second sub-layer, the first sub-layer is located at a side of the fourth conducting line adjacent to the substrate, and the second sub-layer is located at a side of the fourth conducting line away from the substrate;
an orthographic projection of the fourth conducting line on the substrate covers the orthographic projection of the dam structure on the substrate.

10. The display panel according to claim 8, further comprising a bending area, wherein the bending area is located at a side of the dam structure away from the display area, the wiring layer further comprises a fifth conducting line, at least a portion of the fifth conducting line is located in the bending area, and the first conducting member extends to a side of the bending area adjacent to the display area and is electrically connected to the fifth conducting line;
the display panel further comprises a third conducting member, the third conducting member is located at a side of the bending area away from the display area, and the third conducting member and the fifth conducting line are electrically connected to each other and are located in different layers;
the third conducting member and the first conducting member are disposed in a same layer.

11. The display panel according to claim 8, further comprising a bonding area and a chip, wherein the bonding area is located at a side of the dam structure away from the display area, the chip is disposed in the bonding area, and the chip is electrically connected to the first conducting line and the first conducting member;
the wiring layer further comprises a sixth conducting line, at least a portion of the sixth conducting line is located in the bonding area, and the sixth conducting line is electrically connected to the chip and the first conducting member.

12. The display panel according to claim 11, further comprising a second wire-changing area and a fourth through-hole connection structure, wherein the second wire-changing area is located at a side of the bonding area adjacent to the display area, the fourth through-hole connection structure is located in the second wire-changing area, the sixth conducting line extends to the second wire-changing area, the sixth conducting line is electrically connected to the first conducting member through the fourth through-hole connection structure.

13. The display panel according to claim 1, wherein the partition structure further comprises a first partition portion and a second partition portion, the second partition portion is disposed at a side of the first partition portion away from the substrate, an orthographic projection of the first partition portion on the substrate falls within an orthographic projection of the second partition portion on the substrate, and the second conducting line is electrically connected to the first partition portion;
a material of the second partition portion comprises an electrically insulating material, or a material of the second partition portion comprises an electrically conductive material.

14. The display panel according to claim 13, wherein the first touch-control member comprises a third partition portion, and the third partition portion and the first partition portion are disposed in a same layer and are electrically insulated from each other;
the first touch-control member further comprises a fourth partition portion, the fourth partition portion is disposed at a side of the third partition portion away from the substrate, and the fourth partition portion and the second partition portion are disposed in a same layer and are electrically insulated from each other;
an orthographic projection of the third partition portion on the substrate falls within an orthographic projection of the fourth partition portion on the substrate.

15. The display panel according to claim 2, further comprising a light-emitting functional portion and a first electrode, wherein the light-emitting functional portion is disposed in the second opening, and the light-emitting functional portion is spaced from each partition sub-structure;
the first electrode is located at a side of the light-emitting functional portion adjacent to the substrate, and the first electrode is electrically insulated from the partition structure;
the display panel further comprises a second electrode, the second electrode is located at a side of the light-emitting functional portion away from the substrate, and the second electrode is electrically connected to at least one of the plurality of partition sub-structures.

16. The display panel according to claim 15, further comprising a first insulating layer, wherein the first insulating layer is disposed between the partition structure and the first electrode, the first insulating layer defines a third opening, the third opening is located corresponding to the second opening, at least a portion of the light-emitting functional portion is disposed in the third opening, and the third opening exposes the first electrode;
the orthographic projection of at least one of the plurality of partition sub-structures on the substrate is located at a periphery of an orthographic projection of the third opening on the substrate.

17. The display panel according to claim 15, wherein the first electrode and the wiring layer are disposed in a same layer and are electrically insulated from each other.

18. The display panel according to claim 15, wherein the wiring layer is located at a side of the first electrode adjacent to the substrate, and the wiring layer is electrically insulated from the first electrode;
the display panel further comprises a second insulating layer, and the second insulating layer is disposed between the wiring layer and the first electrode.

19. A display panel, comprising a display area and a first wiring area, the first wiring area being located at a side of the display area, and the display panel comprising:
a substrate;
a first partition structure disposed at a side of the substrate, and the first partition structure defines a second opening;
a second partition structure, the second partition structure and the first partition structure being disposed in a same layer and are electrically insulated from each other, and the second partition structure being also a first touch-control member;
a wiring layer comprising a first conducting line and a second conducting line, the first conducting line being electrically connected to the first partition structure, at least a portion of the first conducting line being located in the first wiring area, the second conducting line being electrically connected to the second partition structure, and at least a portion of the second conducting line being located in the display area, and a first conducting member, at least a portion of the first conducting member being located in the first wiring area, and the first conducting member and the second conducting line being electrically connected to each other and being located in different layers.

20. A display device, comprising the display panel according to claim 1.
